(19) United States
(12) Patent Application Publication
(10) Pub. No.: US 2007/0045643 A1
(43) Pub. Date: Mar. 1, 2007

(54) Substrate-based white light diode

(76) Inventor: Shih-Lung Liu, Pingjhen City (TW)

Correspondence Address: TROXELL LAW OFFICE PLLC, SUITE 1404, 5205 LEESBURG PIKE, FALLS CHURCH, VA, 22041, US

(21) Appl. No.: 11/212,733

(22) Filed: Aug. 29, 2005

(51) Int. Cl. H01L 33/00; H01L 21/00

(52) U.S. Cl. 257/98; 257/100; 438/29; 257/E33.061

(57) ABSTRACT

A substrate-based white light diode construction and manufacturing process comprised of having a blue-light chip attached to a substrate; blue-light chip and substrate circuitry contact being connected with a gold plated wire; blue-light chip inlaid into cavity of a mold; and fluorescent glue powder or cake being filled and preheated into fluid before being compressed into the cavity to bind and cover up blue-light chip.

### BACKGROUND OF THE INVENTION

(a) Field of the Invention

The present invention is related to a white light diode and more particularly, to a construction of and manufacturing process of the substrate-based white light diode that improve production capacity of and provide effective control of light convergence and hue of the finished product.

(b) Description of the Prior Art

Conventionally in the manufacturing process of a white-light diode, colored light emitted from blue-light chip is radiated through a fluorescent layer with a specific wavelength to be incorporated with that of the fluorescent layer into the coverage of white-light wavelength so to present the white light results. Therefore, the white-light diode is essentially comprised of blue-light chip and fluorescent layer with a given wavelength.

The manufacturing process of the prior art for the white-light diode involves having first the blue-light chip adhered to a bulk with conductive silver glue (depending on the type of the diode, the bulk may be related to a bow or substrate; the bulk is related to the latter in the present invention); the bulk is then heated at 150° C. for one and half an hours for the glue to get hardened and the blue-light chip to get set on the bulk before connecting the blue-light chip to the circuit contact of the bulk with gold plated wire; a transparent glue is then injected into the top layer of the bulk to cover up the blue-light chip; the transparent glue is baked at 130° C. for two hours to get hardened; a fluorescent glue is applied to the top layer of the transparent glue; and the bulk is further baked at 150° C. for one hour for the fluorescent glue to get hardened. Accordingly, the colored light emitted from the blue-light chip radiates through the fluorescent glue with a specific wavelength for the wavelength of the blue-light chip to be incorporated with that of the fluorescent glue to present the white light emitting diode.

However, the manufacturing process of the prior art for the white-light diode has to go through multiple steps of coating, heating and baking of the transparency insulation glue and the fluorescent glue. The process is minute and complicated, prevents from improved production capacity due to failure in manufacturing product in even smaller size, and blamed for flaw of inconsistency in light convergence and hue of the finished product of the white-light diode due to the absence of an easier control of the thickness of the insulation glue and fluorescent glue.

### SUMMARY OF THE INVENTION

The primary purpose of the present invention is to provide a construction of and a manufacturing process of a substrate-based white light diode that allows effective control of the consistent quality of the white-light diode by prescribing the composition ratio of the fluorescent powder of the glue.

To achieve the purpose, the chip is first attached to the substrate and backed at 150° C. for one and half an hours; the blue-light chip is then connected to the contact of the substrate circuit with gold plated wire; the substrate is then placed in a preheated mold with the blue-light chip inlaid in the cavity; glue or cake containing fluorescent powder is filled into the mold to be heated into fluid of higher viscosity before being compressed into the cavity wherein the glue and the blue-light chip are bound to each other; the fluorescent powder in the glue gradually flows to the channel fixed by the mold to cover upon the surface of the blue-light chip; the powder or the cake is then transformed into yellow insulation to complete the process after the substrate is cooled and hardened.

### BRIEF DESCRIPTION OF THE DRAWINGS

FIG. 1 is a schematic view showing a construction of a substrate-based white light diode of the present invention.

FIG. 2 is a flow chart showing a manufacturing process of the present invention.

FIG. 3 is a schematic view showing the relative arrangement between blue-light chip and substrate of the present invention.

FIG. 4 is a layout showing a mold used in the manufacturing process of the present invention.

FIG. 5 is a side view of the mold used in the manufacturing process of the present invention.

FIG. 6 is a sectional view showing a blue light chip is inlaid into a hole of the dies.

### DETAILED DESCRIPTION OF THE PREFERRED EMBODIMENTS

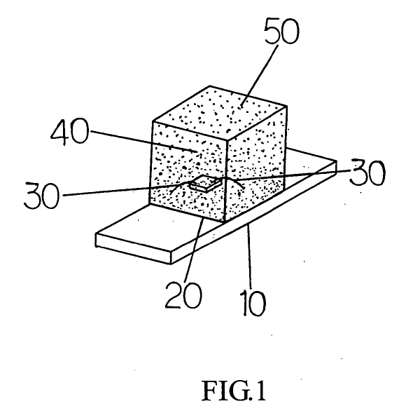

Referring to FIG. 1 for a basic construction of a white-light diode of the present invention is comprised of a substrate (10) attached thereon a blue-light chip (20), the circuit contact of the substrate (10) being connected to the blue-light chip (10) with a gold plated wire (30), the surface of the blue-light chip (20) being coated with a fluorescent layer (40) with a given wavelength, and the entire blue-light chip (20) including the gold plated wire (30) and the fluorescent layer (40) being covered with a yellow insulation layer (50). Accordingly, with the circuit contact of the substrate (10) conducted, the blue light emitted from the blue-light chip (20) is radiated through the fluorescent layer (40) with a given wavelength for the light wave of the blue-light chip (20) ranging between 430 mm˜475 mm to be incorporated with that from the fluorescent layer to form a light with its wavelength falling into the wavelength range of the white light to present the white light effect.

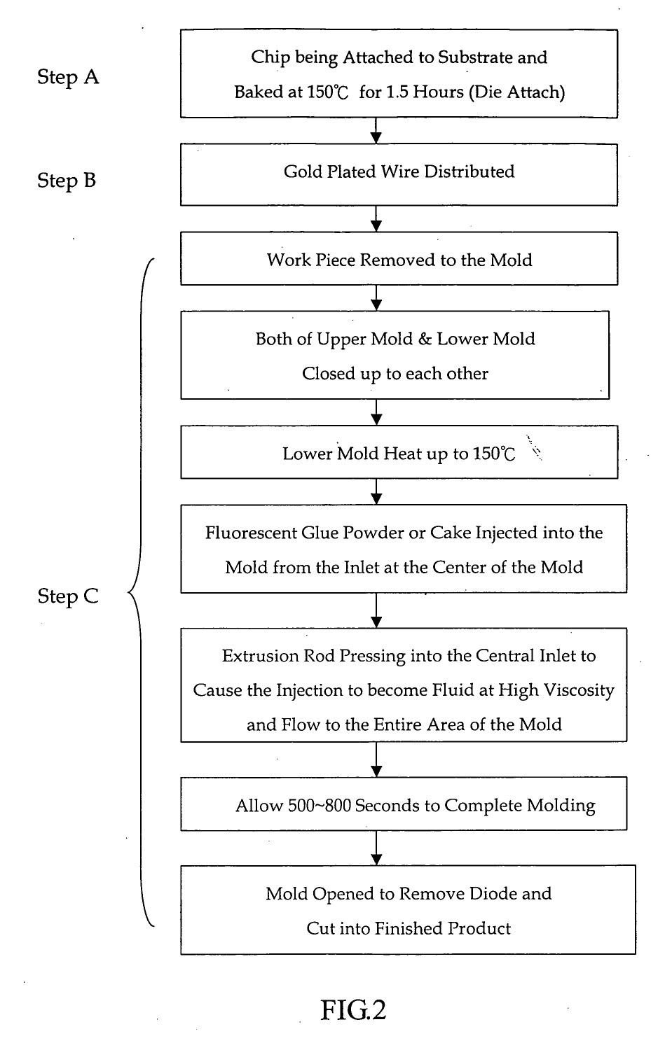

Now referring to FIG. 2, the manufacturing process for the substrate-based white-light diode is comprised of the following steps:

Step A: A mounting gel is used to attach the blue-light chip onto the substrate, and the substrate is baked at 150° C. for one and half an hours to secure the blue-light chip onto the substrate;

Step B: The blue-light chip is connected to the circuit contact of the substrate with a gold plated wire; and

Step C: A fluorescent glue powder or cake containing fluorescent powder and transparent insulation glue is injected to where the blue-light chip is connected with the gold plated wire, and the fluorescent glue is bound to the substrate to be hardened in shape under continuous heating and pressurizing (150° C. for 500˜800 seconds).

Wherein, in the process for the fluorescent glue powder or cake to be heated and hardened, the fluorescent powder in the transparent insulation glue is gradually settling down towards the blue-light chip to cover up on the surface layer of the blue-light chip to become a fluorescent layer. Meanwhile, the process is concluded when the fluorescent glue turns into yellow insulation glue to become a yellow insulation layer.

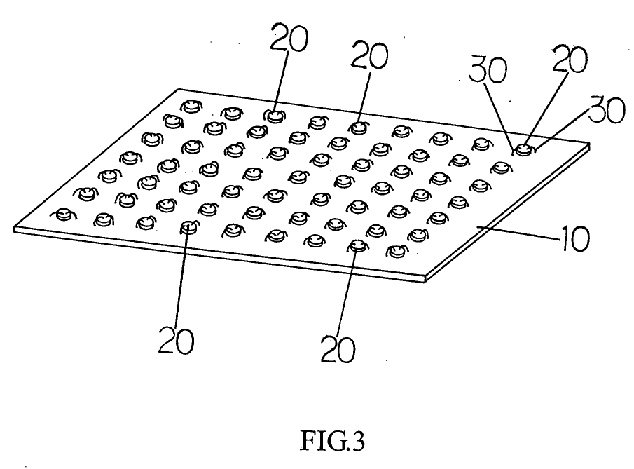

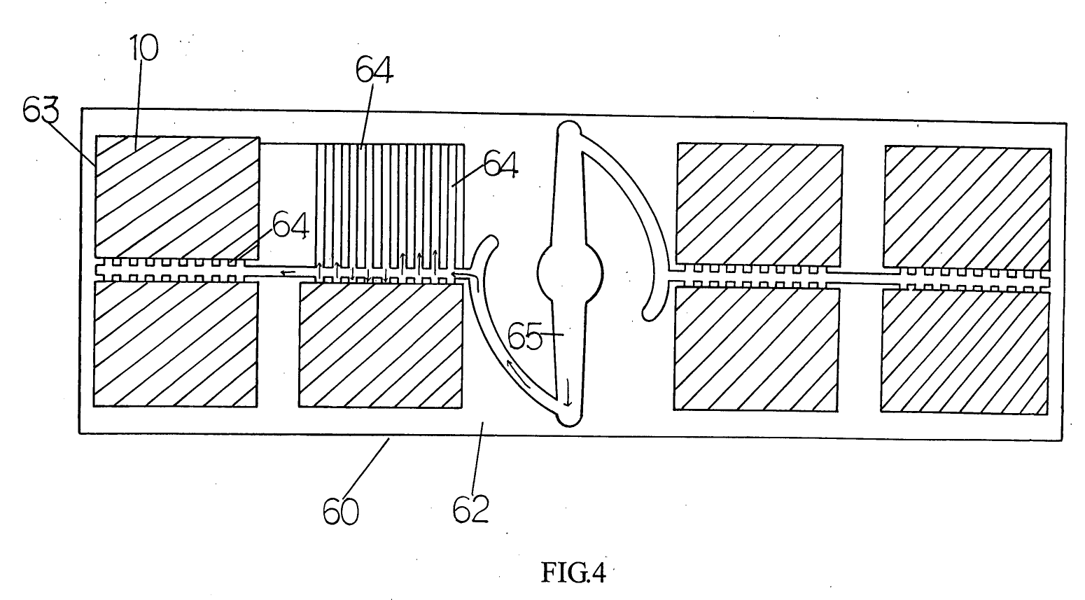

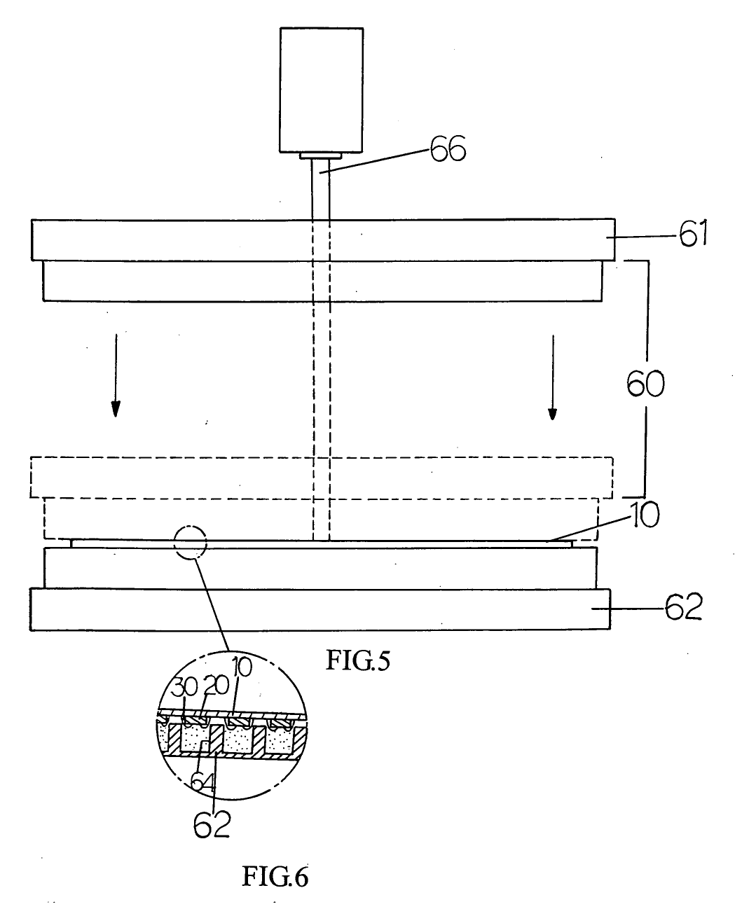

As illustrated in FIGS. 3 and 4, the present invention allows the manufacturing of multiple white-light diodes. Multiple blue-light chips (20) are arranged at the same time on the substrate (10) as illustrated in FIG. 3 with each blue-light chip (20) individually connected to its corresponding circuit contact of the substrate (10) with the gold plated wire (30). A mold as illustrated in FIGS. 4 and 5 is used to carry out the injection and hardening processed for the fluorescent glue powder or cake. Wherein the mold (60) is comprised of an upper mold (61) and a lower mold (62) abutted to each other. The substrate (10) is placed in a mold stock (63) at where between the upper mold (61) and the lower mold (62) and as illustrated in FIGS. 4 and 6, multiple cavities (64) are provided on the mold (6) to abutted to the blue-light chip (2) on the substrate (10). Each cavity (64) is connected through with a main runner (65) and an extruder (66) is disposed at the main runner to allow the fluorescent glue powder or cake into each cavity (64).

Therefore, in the course of injection and hardening for the fluorescent glue powder or cake and the substrate, the substrate (10) attached with the blue-light chip (20) and the gold plated wire (20) is placed in the preheated mold (60) with the blue-light chip (20) on the substrate (10) inlaid into the cavity (64). The fluorescent glue powder or cake in solid state is filled into the main runner (65) of the mold (60) by means of the extruder (66). When heated by the mold (60), the fluorescent glue powder or cake transforms into fluid of high viscosity and is injected into the cavity (64) as compressed by the extruder (66) to be bound to the blue-light chip (20). The fluorescent glue is bound to the substrate and hardened when subject to continuously applied pressure and heat for a period of approximately 500˜800 seconds. In the hardening process, the fluorescent powder mixed in the fluorescent glue gradually flowing to a mold channel fixed by the mold to cover upon the surface of the blue-light chip. Meanwhile the fluorescent glue turns into a yellow insulation glue, and gets cooled and hardened to conclude the manufacturing process of the white-light diode of the present invention. The substrate is then cut into finished product depending on the area of the substrate contributing to each blue-light chip.

The present invention by saving the work hours and procedures to apply applied coating, heating and baking respectively for the fluorescent glue and the transparent insulation glue as found with the process of the prior art promotes the production capacity of the white-light diode and achieves consistent quality of the white-light diode due to effective control of the thickness of the fluorescent glue by prescribing the composition ratio of the fluorescent powder of the fluorescent glue.

The present invention for providing an improved construction of and a manufacturing process of white-light diode to effectively eliminate the flaws of failure in effective control of the light convergence and hue of the finished product due to inconsistent thickness of the insulation glue and fluorescent glue of the substrate-based white-light diode of the prior art, this application for a utility patent is duly filed accordingly. However, it is to be noted that that the preferred embodiments disclosed in the specification and the accompanying drawings are not limiting the present invention; and that any construction, installation, or characteristics that is same or similar to that of the present invention should fall within the scope of the purposes and claims of the present invention.

I claim,

1. A substrate-based white light diode manufacturing process includes the following steps:
Step A: a blue-light chip being attached to a substrate;
Step B: the blue-light chip being connected to the circuit contact of the substrate with a gold plated wire; and
Step C: A fluorescent glue powder or cake containing fluorescent powder and transparent insulation glue being injected to where the blue-light chip is connected with the gold plated wire, and the fluorescent glue is bound to the substrate to be hardened in shape under continuous heating and pressurizing; wherein, in the process for the fluorescent glue powder or cake to be heated and hardened, the fluorescent powder in the transparent insulation glue gradually flowing to the blue-light chip to cover up on the surface layer of the blue-light chip to become a fluorescent layer; and the process being concluded when the fluorescent glue turns into yellow insulation glue to become a yellow insulation layer.

2. The substrate-based white light diode manufacturing process of claim 1, wherein the blue-light chip is attached to the substrate by means of a mounting gel, and the heated at 150° C. for one and half an hours to secure the blue-light chip onto the substrate.

3. The substrate-based white light diode manufacturing process of claim 1, wherein, during the injection and hardening for the fluorescent glue powder or cake and the substrate, the substrate attached with the blue-light chip and the gold plated wire is placed in the preheated mold with the blue-light chip on the substrate inlaid into the cavity; and the fluorescent glue powder or cake in solid state is filled into the main runner of the mold by means of the extruder.

4. A substrate-based white light diode is comprised of having a blue-light chip attached to a substrate; the blue-light chip being connected to the circuit contact of the substrate by means of a gold plate wire; the surface of the blue-light chip being coated with a fluorescent layer with a given wavelength of 430 mm˜475 mm; the blue-light chip including the gold plated wire and the fluorescent layer being covered up with a yellow insulation layer; the circuit contact of the substrate being conducted; the blue light emitted from the blue-light chip being radiated through the fluorescent layer with a given wavelength of 430˜475 mm; and the wavelength of the blue-light chip being incorporated with that from the fluorescent layer to present the white light effect.
